(19) United States
(12) Patent Application Publication
(10) Pub. No.: US 2008/0053524 A1
(43) Pub. Date: Mar. 6, 2008

(54) Solar cell panel integrated with a conforming array of miniature lenses

(76) Inventor: Kurt Lehovec, Los Angeles, CA (US)

Correspondence Address: KURT LEHOVEC, 200 S. WESTMORELAND AV., LOS ANGELES, CA, 90004, US

(21) Appl. No.: 11/514,407

(22) Filed: Sep. 1, 2006

(51) Int. Cl. H01L 31/00

(52) U.S. Cl. 136/259

(57) ABSTRACT

An array of miniature lenses overlays a silicon solar cell panel generating a conforming array of intensely illuminated spots. A drastic saving of silicon material is achieved by restricting the size of the solar cells of the panel in accordance with the size of the sun's image.

### BACKGROUND OF THE INVENTION

Solar cells are one of the renewable energy sources in the forefront of solving the present energy crisis. Most solar cells are silicon based.

Improvements of their efficiency and/or lowering their cost are required to make them competitive with conventional energy sources.

A solar cell provides a current and a voltage output under solar illumination. Concentration of the solar radiation on a smaller area of the solar cell does not increase its current output, but does enhance its voltage output. Thus arrangements have been devised to concentrate the solar radiation on a small size solar cell by means of a large lens or mirror. These arrangements are bulky and costly and thus inappropriate for an inexpensive solar energy conversion from a large area. Moreover extremely intense radiation is unwarranted because it causes an excessive solar cell temperature.

### SUMMARY OF THE INVENTION

My invention integrates a large area solar cell with an array of inexpensive miniature optical means to generate a conforming array of brightly illuminated spots on the large area solar cell. This inhomogeneous solar energy distribution enhances the voltage output of the solar cell and thus its efficiency.

Ordinary solar cells have a grid of contact lines, which block part of the solar radiation. Thus concentrating the solar radiation on spots between them improves the efficiency of the solar cell further.

The not illuminated regions of a conventional solar cell represent a parasitic shunt load resistor consisting of a diode, which is forward biased by the solar cell voltage. Thus the efficiency of my solar cell is further improved by reducing the area of the not illuminated solar cell regions. This is achieved by replacing the large area solar cell by a panel of miniature solar cells on which the solar radiation is focused by the lens array.

The amount of silicon used for such a panel of separated miniature solar cells integrated with focusing optics is a small fraction of the amount of silicon in a conventional solar cell without focusing means.

This results in a considerable cost saving.

### BRIEF DESCRIPTION OF THE DRAWINGS

Three preferred embodiments of my invention are illustrated by the following drawings in which

FIG. 1 is a vertical cross-section through an ordinary silicon solar cell integrated with an overlaid transparent corrugated sheet containing an array of molded miniature lenses to produce a corresponding array of intensely illuminated spots on the solar cell.

FIG. 2 is a vertical cross-section through a miniature solar cell panel consisting of spaced miniature n-type conductivity regions on a p-type conductivity silicon substrate integrated with the conforming array of miniature lenses of FIG. 1.

FIG. 3 is a vertical cross-section through a solar cell panel integrated with an array of lenses in which the miniature solar cells of the panel are physically separated entities imbedded in an insulating retaining matrix.

I like to emphasize that these drawings are not made to scale with some dimensions greatly exaggerated for clarity of presentation.

### PREFERRED EMBODIMENTS

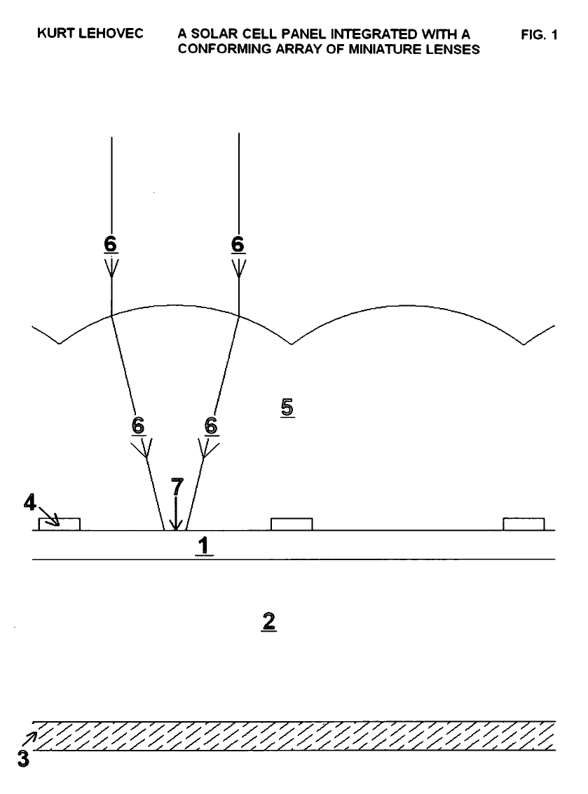

Referring to FIG. 1, there is shown a vertical cross-section through a conventional solar cell consisting of an n-type conductivity layer 1 on a p-type conductivity substrate 2 with a metal base contact 3 and a grid of metal contact lines 4. My invention consists in integrating this conventional solar cell with an overlaid array of semi-planar lenses 5, which focus the incident solar radiation 6 into a conforming array of sun images on the n-layer 1. This has been indicated for one lens by two sun beams 6 producing a sun image 7. The array of lenses 5 is molded into a transparent material of a thickness about equal to the focal length of the lenses.

The array of lenses can be two-dimensional with spherical lenses, in which case the sun image is a disk, or one-dimensional with cylindrical lenses in which case the sun image is a line. The circular periphery of the spherical lenses has been truncated into a quadrangle to fit the lenses into a dense pattern covering the entire surface of the solar cell. The truncation could also be hexagonal to create a honey comb pattern.

The solar cell with integrated optics of FIG. 1 has two advantages over the conventional solar cell without optics:

The focusing of the sun light avoids the loss of effective radiation by the contact grid lines 4. And the focused radiation enhances the open circuit photo-voltage significantly, as shown by the following quantitative considerations:

The focusing of the incident sun light enhances the light intensity at the sun image by the ratio of the lens area to the area of the sun image.

The lens area for a quadrangular array of spherical lenses is the square of the grit length.

The image of the sun by a spherical lens is a disk with a diameter of about 1/200 of the focal length of the lens. Thus the area of the sun image, being one forth of the square of this diameter, timesπ, is about one fifty thousandth of the square of the focal length.

Consequently, the ratio of the lens area to the area of the sun image is about 50000 times the square of the ratio of the grit length to the focal length. Considering the focusing by a quadrangular array of spherical lenses of a focal length equal to the grit length enhances the light intensity at the sun images fifty thousand times.

The open circuit photo-voltage of a conventional silicon solar cell increases by 2.3/40 volts for each 10 fold increase in the light intensity. Thus the cited spherical lens design provides an increase in the open circuit photo-voltage of 0.27 volts. This is a very significant increase, considering that the open circuit photo-voltage of a conventional silicon solar cell exposed to unfocused sun light is only about 0.6 volt.

Considering now a one-dimensional array of cylindrical lenses of a width equal to their focal length, the light intensity at the sun image is enhanced only by the factor 200, which still provides the significant increase of 0.13 volts of the open circuit photo-voltage.

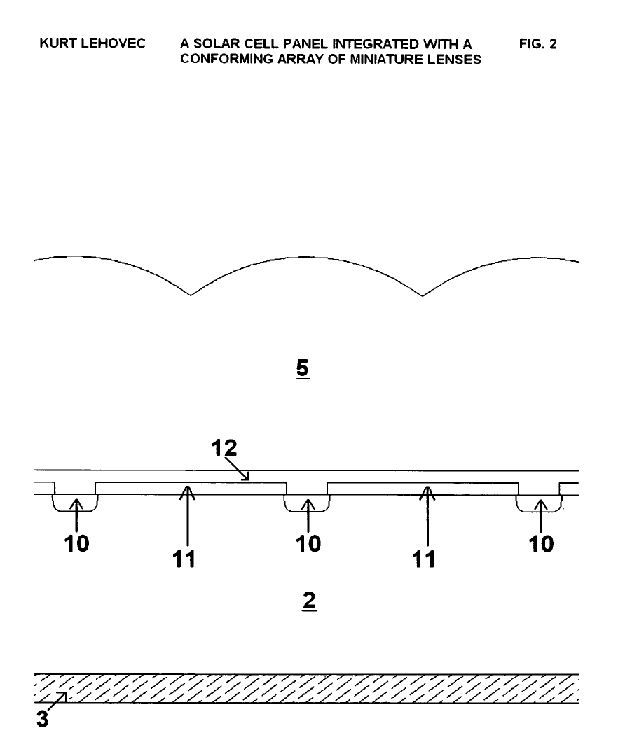

However these increases of the open circuit photo-voltage will not be fully realized, because of the parasitic load resistor of the not-illuminated forward biased p/n junction diode. This detrimental effect is diminished by reducing the not-illuminated area around the sun image. FIG. 2 represents a vertical cross-section through another embodiment of my invention, in which a drastic reduction of the not-illuminated portion of the solar cell has been achieved by replacing the uniform n-layer 1 of the solar cell of FIG. 1 by a panel of n-islands 10 located at the sun images generated by the array of lenses 5. These islands 10 need only be slightly larger than the sun image, if vertical incidence of the solar radiation on the solar panel is maintained by a tracking system of the sun. Without it, the size of the islands should be a small multiple of the sun image to capture obliquely incident sun light.

The n-islands 10 have been generated by gaseous diffusion of the n-type dopant arsenic into the p-type silicon slice 2 through openings in the silicon oxide layer 11. The transparent conducting tin oxide film 12 interconnects electrically the islands 10 and connects them to the outside terminal of this miniature solar cell panel. The contact grid lines 4 of FIG. 1 are not necessary, because the large area covered by the tin oxide film 12 provides sufficient conductance.

While the parasitic load of the not illuminated areas has now been practically eliminated in this embodiment, the not illuminated silicon areas represent a tremendous waste of silicon. Silicon is a major cost factor of solar cells.

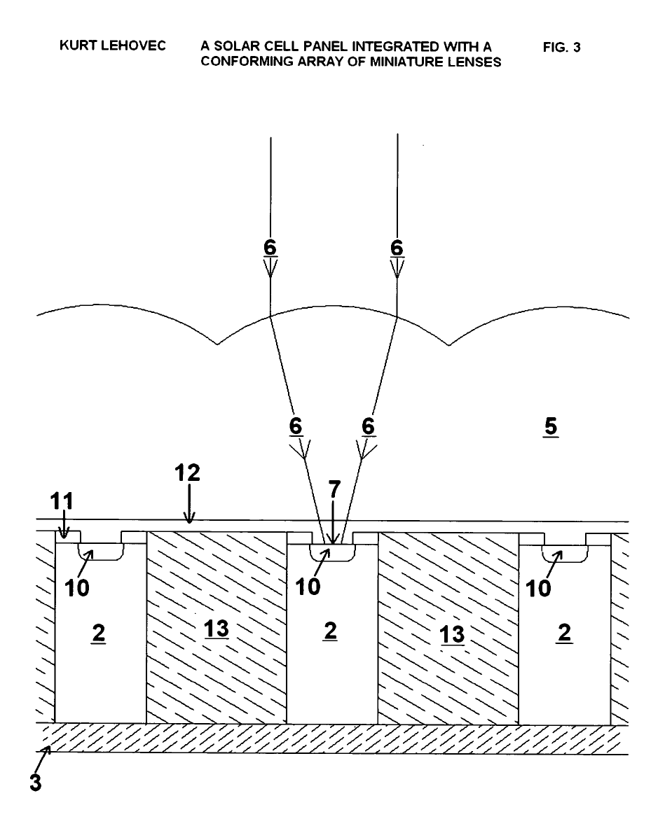

Most of this waste of silicon is eliminated by the embodiment of my invention shown in the vertical cross-section of FIG. 3. In this embodiment the miniature solar cells of FIG. 2, each consisting of an n-island 10 and the shared underlying p-layer 2, have been replaced by separated entities, each comprising an n-island 10 and only the underlying p-layer 2, which is now not very much larger than the n-island.

These separated miniature solar cells are contained in an insolating matrix 13. The layer 11 is the remains of the silicon oxide film of FIG. 2, used in the production of the n-islands, and the layer 12 is the tin oxide film interconnecting electrically the separated miniature solar cells.

These separated miniature solar cells are pedestals in the case of the two-dimensional array of spherical lenses, and ridges in the case of the one-dimensional array of cylindrical lenses.

These structures are made from the silicon slice of FIG. 2 by cutting or by the chemical etching procedure described in the paper “Electrochemical etching in HF solution for silicon micromachining” by G. Barillaro, A. Nannini and M. Piotto published in SENSORS AND ACTUATORS A 102 (2002) 195 - 201, WWW.ELSEVIER.COM/LOCAT/SNS.

To appreciate the tremendous saving of silicon by the embodiment of FIG. 3, consider the following numerical examples, first for the two-dimensional array of spherical lenses with miniature solar cell pillars, and then for the one dimensional array of cylindrical lenses with miniature solar cell ledges.

| | | |
|---|---|---|
| Grid length of the two dimensional array | 1 | mm |
| Lens area | 1 | mm square |
| Focal length of the spherical lens | 1 | mm |
| Diameter of the sun image | 0.005 | mm |
| Diameter of the n-layer | 0.05 | mm |
| Side length of a square pillar | 0.1 | mm |
| Its cross-sectional area | 0.01 | mm square |

| | |
|---|---|
| Cross-sectional area/lens area | 1% |

Thus 99% of silicon is saved by this miniature solar cell panel of FIG. 3 compared to a conventional solar cell

Consider now a panel of cylindrical lenses of a width equal to their focal length of 1000 microns: The width of the sun image is 5 microns.

Choosing 50 microns for the width of the n-layer and 100 microns for the width of the p-ledge, 90% of the silicon is saved compared to a conventional solar cell.

These considerations do not include the loss of silicon involved in the production of the silicon pillars or ledges.

While the saving of silicon is greater for the two dimensional array of spherical lenses than that for the one dimensional array of cylindrical lenses, the handling of ledges is easier than that of pillars, and the cylindrical lens design may be preferable.

As many apparently widely different embodiments of this invention may be made without departing from the spirit and scope thereof, it is to be understood that this invention is not limited to the specific embodiments herein described, except as defined in the following claims.

What is claimed is;

1. A solar cell integrated with an overlaid array of optical means to generate a conforming array of brightly illuminated spots on said solar cell by focusing the sun on said solar cell.

2. The solar cell of claim 1 with said optical means being lenses molded in a transparent corrugated sheet.

3. The integrated solar cell of claim 1 comprising a panel of miniature solar cells on which the sun radiation is focused by said array of optical means.

4. The integrated solar cell of claim 3 with said panel of miniature solar cells consisting of spaced miniature doped regions of one conductivity type on a silicon substrate of the opposite conductivity type.

5. The integrated solar cell panel of claim 3 with said miniature solar cells being separated entities imbedded in an insulating retaining matrix.

6. A procedure for preparation of said miniature solar cells of claim 5, said procedure including providing of a slice of a semiconductor of one conductivity type with a densely spaced array of regions of the other conductivity type, and physical separation of said regions of the other conductivity type with the underlying part of said slice of the one conductivity type to obtain said separated miniature solar cells.

7. The integrated solar cell panel of claim 5 with said miniature solar cells made from silicon.
